(19) United States
(12) Patent Application Publication
(10) Pub. No.: US 2006/0054979 A1
(43) Pub. Date: Mar. 16, 2006

(54) Method for fabricating a drain/source path

(76) Inventors: Philipp Kratzert, Berlin (DE); Norbert Schulze, Radebeul (DE); Juerg Haufe, Dresden (DE); Roland Haberkern, Garching (DE); Stephan Riedel, Dresden (DE); Patrick Haibach, Dresden (DE)

Correspondence Address: SLATER & MATSIL LLP, 17950 PRESTON ROAD, SUITE 1000, DALLAS, TX, 75252, US

(21) Appl. No.: 11/010,643

(22) Filed: Dec. 13, 2004

(30) Foreign Application Priority Data
Dec. 12, 2003 (DE) 103 58 664.4

(51) Int. Cl. H01L 21/8238; H01L 29/94

(52) U.S. Cl. 257/410; 257/411; 438/216; 438/261

(57) ABSTRACT

A method for fabricating a drain/source path is provided, in which essentially firstly a nitride layer is applied, on which a TEOS layer is then patterned. The patterning is effected in a simplified manner by virtue of the fact that the nitride layer acts as an etching stop layer during the etching away of the TEOS layer.

The present invention relates to a method for fabricating a drain/source path in accordance with patent claim 1.

One of the most important development aims of semiconductor memory technology consists in embodying ever smaller memory cells, that is to say in using ever smaller silicon areas per stored information unit. In this case, the problem arises that, on the one hand, the operating voltage used for customary semiconductor arrangements is increasingly reduced as a result of the advancing spatial miniaturization. On the other hand, however, far higher voltages than are provided for standard components are often necessary for exploiting certain physical effects.

Thus, DE 100 36 911 A1, for example, discloses the construction of an NROM cell in which firstly an implantation of dopant is performed using an auxiliary layer in order to fabricate “LDD” regions (Lightly Doped Drain) at the edges of the source region and of the drain region that face the channel region. Doped regions having weak electrical conductivity with the opposite sign to that of the basic doping are thus fabricated. This implantation is therefore effected for n-type doping in the case of a p-type well. Preferably, a so-called “pocket implantation” for the conductivity type of the basic doping, although with a somewhat higher dopant concentration, is additionally performed in a manner known per se in order to obtain a shaper boundary of the source region or drain region.

The basic structure of a drain/source path of a memory cell of this type corresponds to the drain/source path of a MOS transistor. In order to increase the dielectric strength of a component of this type, it would then be necessary to draw apart the drain/source regions. For this purpose, it is known to pattern a so-called spacer, which, as specified in DE 100 36 911 A1, is provided for the patterning of the gate structure. However, a measure of this type is extremely complicated since additional mask steps are necessary. A wider spacer is often used for this in order that the source/drain regions are drawn apart. Said spacer consequently initially has to be patterned in wider fashion in order then to etch back said spacer again.

The invention is thus based on the object of providing a method for fabricating a drain/source path which provides a drain/source path having an elevated dielectric strength with the least possible outlay. This object is achieved according to the invention by means of the measures specified in patent claim 1.

By virtue of the fact that firstly a first spacer layer is applied on the structure defining the gate contact and a second spacer layer is at least partly arranged on said first spacer layer, the material of the first spacer layer being chosen such that the first spacer layer acts as an etching stop during the etching of the second spacer layer, it is possible, without additional maskings, firstly to use a wide spacer for providing the source/drain implantation, which spacer can be etched back by simple means in order to continue in the customary patterning. By virtue of the provision of the first spacer layer as an etching stop, the surface of the gate oxide remains protected during the etching back of the second spacer layer. This also avoids the provision of additional masking steps.

Further advantageous refinements of the invention are specified in the subordinate patent claims.

In particular by virtue of the fact that the second spacer layer serves together with the first spacer layer as a mask for drain/source implantation, a simple fabrication is possible.

This is aided in particular by the fact that the first spacer layer is a nitride and the spacer layer is a tetraethyl orthosilicate. The fact that, furthermore, it is provided that a first implantation is combined into a boron implantation prior to the fabrication of the arrangement defining the gate structure enables a cost-effective fabrication.

The invention is explained below using an exemplary embodiment with reference to the drawing.

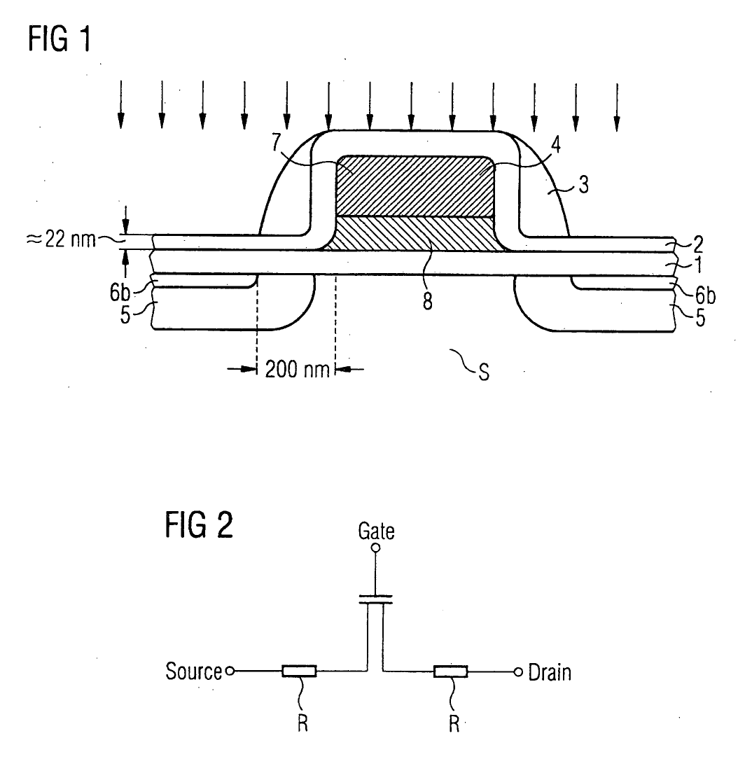

FIG. 1 shows a semiconductor arrangement in which an oxide layer 1 is applied on a substrate S. Said oxide layer may be in multipartite form, e.g. a so-called ONO layer sequence. In this case, a so-called storage layer, e.g. silicon nitride, is applied on a bottom oxide layer (bottom oxide), a further oxide layer (top oxide) being applied on said storage layer as a top boundary layer.

An arrangement (4) defining the dimensions of a gate structure is then applied. Said arrangement 4 may optionally be an auxiliary layer which is replaced by the actual gate construction at a later point in time, or may already be the actual gate construction.

In the exemplary embodiment illustrated in FIG. 1, the arrangement is chosen in such a way that a gate contact 8 is provided above the gate oxide 1 and a covering made of nitride 7 is provided above said gate contact.

When the structure 4 is present, an implantation is effected in the region of source and drain, which is masked by the construction 4. During this implantation, an implantation of the LDD regions 5a and 5b is thus effected at the edges of the source region and of the drain region which face the channel region. Doped regions having weak electrical conductivity with the opposite sign to that of the basic doping would thus be fabricated. This implantation is thus effected with n-type doping in the case of a p-type well, that is to say e.g. as so-called p-LDD implantation. In this case, LDD stands for “lightly doped drain”.

Preferably, a so-called pocket implantation for the conductivity of the basic doping, although with a somewhat higher dopant concentration, is additionally performed in a manner known per se, in order to obtain a sharper boundary of the source region or drain region. In the case of the present embodiment, the three hitherto customary boron implantations that are there, e.g. high-voltage NMOS compensation, p-LDD and antipunch implantation, are provided as overall implantation to form a single process step. A superposition of the p-LDD implantation by the n-LDD implantation is thus effected. Since a greater outdiffusion is effected in the case of boron than in the case of phosphorus, the superposition brings about a flattening of the conductivity gradient and thus stabilized high-voltage properties. In terms of the effects, this method step may consequently rather be referred to as “anti-pocket implantation” since the hitherto customary “pocket implantation” rather leads to a transition of the conductivity regions with a steeper gradient.

The implantation is followed by the construction of a nitride layer, having a thickness of approximately 22 nm in accordance with the present exemplary embodiments. A TEOS layer (tetraethyl orthosilicate) 3 is again applied on said nitride layer and is then etched back to the necessary width for masking of the required concluding drain/source implantation. In order to obtain a breakdown voltage of greater than 15 V, the spacing of the spacers 3 produced in this way is approximately 200 to 215 nm. Production experiments have revealed that a breakdown voltage of approximately 15 V can be obtained when the spacers 3 have a spacing of 250 nm. The spacing of the spacers yields, after implantation, a correspondingly wide spacing of the source regions and drain regions 6a and 6b.

After implantation, it is then possible for the spacer 3 to be further or completely etched away. In this case, it is advantageous that, by virtue of the fact that TEOS was used as material for the spacer 3, the underlying nitride layer 2 acts as an etching stop for protecting the gate oxide layer 1.

The effect of the structure thus obtained has the consequence that resistance regions 7, as are illustrated in the circuit diagram in accordance with FIG. 2, arise as a result of the source region 6a and the drain region 6b being drawn apart. The high voltage between the source and drain regions in relation to the operating voltage that is customary in the technology used can be dropped across said resistance regions.

1-5. (canceled)

6. A semiconductor arrangement, having a multilayered gate oxide on a substrate and having, in the substrate outside the region covered by the gate oxide, a drain region spaced apart from the latter and a source region spaced apart from the latter.

7. A method for fabricating a drain/source path, the method comprising:
forming at least one gate dielectric over a semiconductor body of a first conductivity type;
forming a structure defining a gate contact over the gate dielectric, wherein the structure does not cover the semiconductor body outside the gate contact;
forming a first spacer layer on the structure defining the gate contact and the regions not covered by said structure;
forming a second spacer layer that is at least partly arranged on the first spacer layer; and
removing the second spacer layer, wherein the material of the first spacer layer being chosen such that the first spacer layer acts as an etching stop during removal of the second spacer layer.

8. The method as claimed in claim 7, further comprising performing a drain source implantation into the semiconductor body, wherein the first spacer layer and the second spacer layer jointly serve as a mask for the drain/source implantation.

9. The method as claimed in claim 8, wherein the implantation is effected as a superposition of a p-LDD implantation with an n-LDD implantation.

10. The method as claimed in claim 7, wherein the first spacer layer comprises a nitride layer and wherein the second spacer layer comprises an oxide.

11. The method as claimed in claim 10, wherein forming the second spacer layer comprises performing a TEOS deposition process.

12. The method as claimed in claim 7, further comprising performing a basic implantation that acts as blanket implantation prior to the application of the first spacer layer.

13. The method as claimed in claim 7, wherein forming at least one gate dielectric comprises forming a gate oxide.

14. The method as claimed in claim 13, wherein forming:g at least one gate dielectric comprises forming an oxide-nitride-oxide layer sequence.

15. The method as claimed in claim 7, wherein forming at least one gate dielectric comprises Conning a memory layer sequence, the memory layer sequence comprising a storage layer sandwiched between two boundary layers.

16. The method as claimed in claim 7, wherein the structure defining the gate contact comprises a transistor gate.

17. The method as claimed in claim 7, wherein the structure defining the gate contact comprises a sacrificial structure.

18. A method for fabricating a semiconductor device, the method comprising:
forming at least one gate dielectric over a semiconductor body of a first conductivity type;
forming a structure defining a gate contact over the gate dielectric, wherein the structure does not cover the semiconductor body outside the gate contact;
forming a first spacer on a sidewall of the structure defining the gate contact;
forming a second spacer on the first spacer;
performing a first implantation of ions into the semiconductor body, the first implantation being masked by the first spacer and the second spacer;
removing the second spacer layer, wherein the material of the first spacer layer acts as an etching stop during removal of the second spacer layer; and
after removing the second spacer layer, performing a second implantation of ions into the semiconductor body, the first implantation being masked by the first spacer.

19. The method as claimed in claim 18, wherein the first spacer comprises a nitride spacer and wherein the second spacer comprises an oxide spacer.

20. The method as claimed in claim 19, wherein forming the second spacer comprises performing a TEOS deposition process.

21. The method as claimed in claim 18, wherein forming at least one gate dielectric comprises forming a gate oxide.

22. The method as claimed in claim 21, wherein forming at least one gate dielectric comprises forming an oxide-nitride-oxide layer sequence.

23. The method as claimed in claim 18, wherein forming at least one gate dielectric comprises forming a memory layer sequence, the memory layer sequence comprising a storage layer sandwiched between two boundary layers.

24. The method as claimed in claim 18, wherein the structure defining the gate contact comprises a transistor gate.

25. The method as claimed in claim 18, wherein the structure defining the gate contact comprises a sacrificial structure.
